(19) United States
(12) Patent Application Publication
(10) Pub. No.: US 2021/0011245 A1
(43) Pub. Date: Jan. 14, 2021

(54) SINGLE-POINT DRIVEN AXIAL ADJUSTMENT MECHANISM

(71) Applicant: The Institute of Optics and Electronics, The Chinese Academy of Sciences, Sichuan (CN)

(72) Inventors: Xianchang ZHU, Sichuan (CN); Jian WANG, Sichuan (CN); Lei CHEN, Sichuan (CN)

(21) Appl. No.: 16/627,971

(22) PCT Filed: Dec. 29, 2018
(86) PCT No.: PCT/CN2018/125384

§ 371 Date: Dec. 31, 2019

(30) Foreign Application Priority Data
Mar. 28, 2018 (CN) 201810262331.0

(51) Int. Cl. G02B 7/00; G03F 7/20; H04N 5/225

(52) U.S. Cl. CPC G02B 7/005; H04N 5/2254; G03F 7/70825

(57) ABSTRACT

A single-point driven axial adjustment mechanism for precision axial adjustment of an optical element of a high-resolution imaging system, includes a support base in a bottom layer for fixing and linking of the adjustment mechanisma, a driving mechanism in a middle layer, on which three elastic mechanisms are evenly distributed such that a single-point driving force applied to the driving mechanism is delivered to the three elastic mechanisms, and an element support seat in a top layer for fixedly supporting an optical element to be adjusted. The driving mechanism in the middle layer is configured to move in a horizontal direction in response to the driving mechanism being adjusted, and the three elastic mechanisms evenly distributed on the driving mechanism converts a horizontal movement of the driving mechanism into an axial movement of the optical element support seat.

### FIELD OF THE DISCLOSURE

The present disclosure relates to a precision mechanical device, and more particularly to a single-point driven axial adjustment mechanism for precision axial adjustment of optical elements.

### DESCRIPTION OF THE RELATED ART

With improvement of performance of an optical imaging system, further requirements for adjustment function of an optical element are needed in that: not only the adjustment accuracy of the optical element is required to reach a micron or even sub-micron level; but also higher requirements for the dynamic response time of the adjustment mechanism is needed. Meanwhile, the spatial size of the adjustment mechanism is required to be more compact.

In optical imaging systems, a common position adjustment of an optical element involves an adjustment of the displacement along an optical axis in Z direction. In order to achieve corresponding adjustment of the optical element, the position adjustment of the optical element is realized by three wedge mechanisms in a common mechanism. In a high-resolution imaging optical system, there is a corresponding technical difficulty in adjusting the axial displacement of the optical element by using the wedge adjusting mechanism in that: on one hand, the uniformly distributed wedge mechanisms require a large installation space, which does not conform to the compact size requirements of the high-resolution imaging system for the adjustment mechanism; on the other hand, the adjustment error of the mechanism cannot meet the high-precision adjustment requirements of the optical element.

### SUMMARY

In order to solve the above problems and to obtain a precision adjustment of an optical element of a high-resolution imaging system, the present disclosure proposes a single-point driven axial adjustment mechanism capable of achieving high-precision position adjustment of the optical element in a small space.

With a specific technical solution of the present disclosure, an axial adjustment mechanism for precision axial adjustment of an optical element of a high-resolution imaging system is provided. The axial adjustment mechanism generally includes three layers: a support base located in a bottom layer for fixing and linking of the adjustment mechanism; a driving mechanism located in a middle layer, on which three elastic mechanisms are evenly distributed such that a single-point driving force applied to the driving mechanism is delivered to the three elastic mechanisms; and an element support seat located in a top layer and configured for fixedly supporting the optical element to be adjusted. In the axial adjustment mechanism, the axial adjustment of the adjusted optical element can be achieved by a single-point adjustment.

The present disclosure provides an axial adjustment mechanism for precision axial adjustment of an optical element of a high-resolution imaging system, being characterized in that the driving mechanism located in the middle layer is configured to be guided by a linear guide rail to move in a horizontal direction in response to the driving mechanism being adjusted, and three pairs of levers and elastic adjustment mechanisms are evenly distributed on the driving mechanism to convert the horizontal movement of the driving mechanism into an axial movement of the optical element support seat, achieving an axial adjustment of the optical element.

In the axial precision adjusting mechanism of the present disclosure, the axial adjustment is realized by using three pairs of levers and elastic hinge mechanisms, and deformation amounts in the three elastic hinges are ensured to be the same by adjusting the magnification ratio of the levers, thereby realizing the high-precision axial adjustment of the adjusted optical element.

### BRIEF DESCRIPTION OF THE DRAWINGS

FIG. 1 is a schematic view showing a driving principle of an adjustment mechanism according to an embodiment of the present disclosure.

FIG. 2 is a schematic view of an elastic adjustment mechanism for use in an adjustment mechanism according to an embodiment of the present disclosure.

FIG. 3 is a schematic view showing a lever-type driving principle for use in an adjustment mechanism according to an embodiment of the present disclosure.

FIG. 4 is a general schematic view of an adjustment mechanism according to an embodiment of the present disclosure.

### DETAILED DESCRIPTION OF EMBODIMENTS

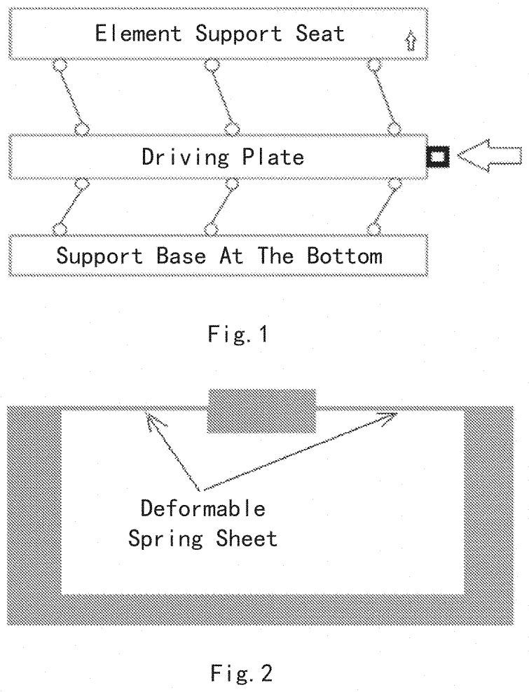

An adjustment mechanism according to the present disclosure will be further described with reference to the accompanying drawings. FIG. 1 is a schematic view showing a driving principle of an adjustment mechanism according to an embodiment of the present disclosure. The adjustment mechanism generally includes three layers: a support base located in a bottom layer for fixing and linking of the adjustment mechanism; a driving mechanism located in a middle layer, on which three elastic mechanisms are evenly distributed such that a single-point driving force applied to the driving mechanism is delivered to the three elastic mechanisms; and an element support seat located in a top layer and used for fixedly supporting an optical element to be adjusted. In the axial adjustment mechanism, the axial adjustment of the adjusted optical element can be achieved by a single-point adjustment.

The present design adopts a three-layer structure in which the support base in the bottom layer and the driving mechanism in the middle layer are laterally driven and guided by a linear guide rail so that the driving mechanism moves in a horizontal direction. Three pairs of lever-type direction-changing mechanisms and elastic hinge adjustment mechanisms are evenly distributed on the driving mechanism in the middle layer so that the horizontal movement of the driving mechanism can be converted into the axial movement of the adjusted optical element.

The elastic hinge mechanism used in the adjustment mechanism is shown in FIG. 2. The elastic hinge mechanism is connected at two ends thereof to the driving mechanism, and is connected at the center thereof to the support seat for the optical element to be adjusted. There are two same segments of deformable spring sheets between the two ends and the center to ensure that only an up-and-down axial deformation occurs in the elastic hinge mechanism in case that a force is applied to the elastic hinge mechanism.

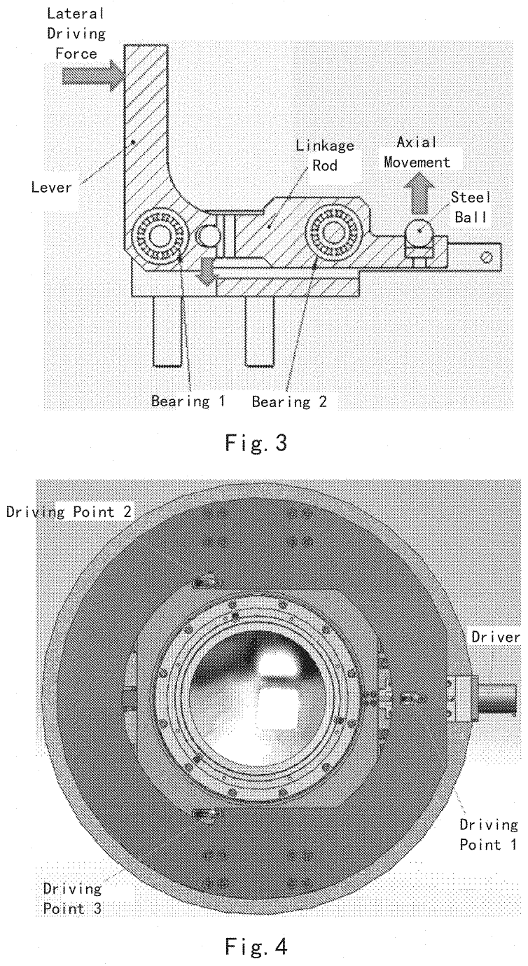

The lever-type direction-changing mechanism used in the adjustment mechanism is shown in FIG. 3 and comprises a lever, bearings, a linkage rod and a steel ball. When the lever-type direction-changing mechanism is subjected to a driving force in the horizontal direction, the lever and the linkage rod are respectively rotated about the corresponding bearings, so that the horizontal movement can be converted into an axial movement, thereby driving the elastic hinge mechanism to deform and realizing the adjustment of the optical element.

The adjusting mechanism of the disclosure realizes the axial adjustment by means of a combination of three pairs of lever-type direction-changing mechanisms and elastic hinge mechanisms, and the deformation amounts of the three elastic hinges are ensured to be the same by adjusting the magnification ratio of the levers, thereby achieving the axial adjustment of the adjusted optical element.

1. An axial adjustment mechanism for precision axial adjustment of an optical element of a high-resolution imaging system, the axial adjustment mechanism comprising
a support base located in a bottom layer for fixing and linking of the axial adjustment mechanism;
a driving mechanism located in a middle layer, on which three elastic mechanisms are evenly distributed such that a single-point driving force applied to the driving mechanism is delivered to the three elastic mechanisms; and
an element support seat located in a top layer and configured for fixedly supporting an optical element to be adjusted,
wherein the axial adjustment mechanism is configured such that an axial adjustment of the adjusted optical element is achieved by a single-point adjustment.

2. The axial adjustment mechanism according to claim 1,
wherein the driving mechanism located in the middle layer is configured to move in a horizontal direction in response to the driving mechanism being adjusted, and three pairs of lever-type direction-changing mechanisms and elastic adjustment mechanisms are evenly distributed on the driving mechanism to convert a horizontal movement of the driving mechanism into an axial movement of the optical element support seat, achieving an axial adjustment of the optical element.

3. The axial adjustment mechanism according to claim 1,
wherein the axial adjustment is realized by a combination of three pairs of lever-type direction-changing mechanisms and elastic hinge mechanisms, and deformation amounts in three elastic hinges are ensured to be the same by adjusting magnification ratios of the levers, thereby achieving the axial adjustment of the adjusted optical element.
